(19) United States
(12) Patent Application Publication
(10) Pub. No.: US 2022/0327682 A1
(43) Pub. Date: Oct. 13, 2022

(54) WAFER MEASURING METHOD AND DEVICE, AND COMPUTER-READABLE STORAGE MEDIUM

(71) Applicant: CHANGXIN MEMORY TECHNOLOGIES, INC., Hefei City, Anhui Province (CN)

(72) Inventor: SHENG-TSUNG TSAO, Hefei (CN)

(73) Assignee: CHANGXIN MEMORY TECHNOLOGIES, INC., Hefei City, Anhui Province (CN)

(21) Appl. No.: 17/435,270

(22) PCT Filed: Mar. 22, 2021
(86) PCT No.: PCT/CN2021/082204

§ 371 Date: Aug. 31, 2021

(30) Foreign Application Priority Data
Mar. 23, 2020 (CN) 202010206801.9

(51) Int. Cl. G06T 7/00; G01N 21/95; H01L 21/66

(52) U.S. Cl. CPC G06T 7/0004; G01N 21/9505; H01L 22/12; G06T 2207/30148

(57) ABSTRACT

The present application relates to the field of semiconductors, and provides a wafer measuring method, a wafer measuring device, and a computer-readable storage medium. The method includes: acquiring an image to be measured of a wafer to be measured and a preset measurement point, and acquiring an abnormal region in the image to be measured; acquiring a target measurement point outside the abnormal region based on the abnormal region if the preset measurement point is in the abnormal region; and measuring the wafer to be measured via the target measurement point. Compared with the prior art, the wafer measuring method and device, and the computer-readable storage medium according to some embodiments of the present application have an advantage in improving accuracy of a wafer measurement result.

### CROSS REFERENCE TO RELATED APPLICATIONS

The present application claims priority to Chinese Patent Application No. 2020102068019, filed on Mar. 23, 2020 and entitled “WAFER MEASURING METHOD AND DEVICE, AND COMPUTER-READABLE STORAGE MEDIUM”, the entire contents of which are incorporated herein by reference.

### TECHNICAL FIELD

The present application relates to the field of semiconductors, and in particular to a wafer measuring method, a wafer measuring device, and a computer-readable storage medium.

### BACKGROUND

A wafer refers to a substrate (also called chip) on which semiconductor transistors or integrated circuits are manufactured. The wafer is a crystal material and is of a circle shape, and materials of the substrate may include silicon, germanium, GaAs, InP, GaN, or the like. The wafer may be processed to have various circuit element structures to become integrated circuit products with specific electrical functions. A common raw material for the wafer is silicon, and there is inexhaustible silicon dioxide on the surface of the earth's crust. The silicon dioxide ore is refined by an electric arc furnace, chlorinated with hydrochloric acid, and then distilled to produce high-purity silicon for preparing the wafer. During a process of manufacturing the circuit elements in the prior art, after the wafer is filmed with a photoetching process, the photoetched wafer shall be generally measured to determine the mass of the wafer.

However, fixed points on the wafer are generally measured in a measurement process in the prior art, which may be easily affected by abnormalities such as particles and scratches on a surface of the wafer and thereby causes the measurement result to have a poor accuracy.

### SUMMARY

An objective of some embodiments of the present application is to provide a wafer measuring method and a wafer measuring device, and a computer-readable storage medium for achieving higher accuracy of measurement of the wafer.

In order to solve the technical problem, an embodiment of the present application provides a wafer measuring method, which includes: acquiring an image to be measured of a wafer to be measured and a preset measurement point, and acquiring an abnormal region in the image to be measured; acquiring a target measurement point outside the abnormal region based on the abnormal region if the preset measurement point is in the abnormal region; and measuring the wafer to be measured via the target measurement point.

Another embodiment of the present application further provides a wafer measuring device, which includes at least one processor, and a memory communicatively connected with the at least one processor, wherein the memory stores instructions executable by the at least one processor, and the instructions, when executed by the at least one processor, cause the at least one processor to execute the aforesaid wafer measuring method.

Still another embodiment of the present application further provides a computer-readable storage medium for storing computer programs, wherein the computer programs, when executed by a processor, cause the processor to implement the aforesaid wafer measuring method.

Compared with the prior art, in some embodiments of the present application, firstly, before measuring the wafer, an image of the wafer to be measured is acquired as the image to be measured, and a position of the preset measurement point and a position and an area of the abnormal region in the image to be measured are acquired. If the preset measurement point is in the abnormal region, the abnormality on a surface of the abnormal region may affect measurement of the wafer. At this point, the wafer to be measured may be measured via the target measurement point as acquired outside the abnormal region based on the abnormal region. Since the target measurement point is disposed outside the abnormal region, the measurement may no longer be affected by the abnormality on the surface of the abnormal region when measuring the wafer to be measured via the target measurement point, thereby effectively improving accuracy of a measurement result of the wafer to be measured.

Furthermore, acquiring the abnormal region in the image to be measured includes: acquiring an area and a position of a region having an abnormality in the image to be measured by comparing the image to be measured with a standard wafer image; and taking the region having the abnormality as the abnormal region.

Furthermore, there are one or more preset measurement points, and the target measurement point has a different position with the preset measurement point. Since the target measurement point is configured to have a different position with the preset measurement point, a reduction in the number of measurement points as caused by a coincidence between the target measurement point and the preset measurement point may be prevented, thereby ensuring accuracy of the measurement result of the wafer to be measured.

Furthermore, acquiring the target measurement point outside the abnormal region includes: dividing the image to be measured into several units; moving by one or more units every time by taking the preset measurement point as a starting point to acquire a detection measurement point; and acquiring the target measurement point once the detection measurement point is outside the abnormal region. Since the detection measurement point is acquired by moving by one or more units every time by taking the preset measurement point as the starting point, it is possible to acquire the target measurement point disposed outside the abnormal region and closest to the preset measurement point in the abnormal region, such that the target measurement point may be prevented from being far away from the preset measurement point, thereby ensuring accuracy of the wafer measurement result.

Furthermore, acquiring the target measurement point outside the abnormal region includes: pre-storing images of a plurality of abnormal wafers as sample images, the sample images including sample abnormal regions and being stored with sample measurement points correspondingly; acquiring the sample image having the same distribution with the abnormal region as a target sample image; and acquiring the sample measurement point correspondingly stored with the target sample image as the target measurement point. The procedure of determining a position of the target measurement point via the pre-stored sample images is relatively simple and requires no complicated calculation, which thereby has a small calculation amount and high measurement efficiency.

Furthermore, acquiring the sample image having the same distribution with the abnormal region as the target sample image includes acquiring the sample image having the same area and position with the abnormal region as the target sample image.

Furthermore, acquiring the sample image having the same distribution with the abnormal region as the target sample image includes: dividing the image to be measured and the sample image into a plurality of detection regions; and acquiring the sample image that is the same as the detection region where the abnormal region is disposed as the target sample image. By dividing the image to be measured and the sample image into a plurality of detection regions to acquire the sample image that is the same as the detection region where the abnormal region is disposed as the target sample image, there is no need to calculate a shape or other parameters of the abnormal region and sample image in detail, which can simplify a comparison process and improve the measurement efficiency.

Furthermore, the sample measurement point correspondingly stored based on the target sample image serves as the target measurement point.

Furthermore, acquiring the abnormal region in the image to be measured includes: dividing the image to be measured into a plurality of detection regions; and acquiring the detection region having an abnormality as the abnormal region. By dividing the image to be measured into a plurality of detection regions and acquiring the detection region having the abnormality as the abnormal region, there is no need to calculate a specific shape and a position of the abnormality, which can effectively simplify the measurement process and improve the measurement efficiency.

Furthermore, acquiring the target measurement point outside the abnormal region includes acquiring the target measurement point in the detection region adjacent to the abnormal region.

Furthermore, dividing the image to be measured into the plurality of detection regions includes dividing the image to be measured into a plurality of annuli or quadrants.

### BRIEF DESCRIPTION OF THE DRAWINGS

One or more examples are exemplarily described by a corresponding figure in accompanying drawings, and these exemplary descriptions do not constitute a limitation to the embodiments. The elements with a same reference sign in the accompanying drawings represent similar elements. Unless otherwise specified, the figures in the accompanying drawings do not constitute a scale limitation.

FIG. 1 is a flowchart of a wafer measuring method according to an embodiment of the present application;

FIG. 2 is a schematic diagram of an image to be measured in a wafer measuring method according to an embodiment of the present application;

FIG. 3 is a schematic diagram of another image to be measured in a wafer measuring method according to an embodiment of the present application;

FIG. 4 is a schematic diagram of still another image to be measured in a wafer measuring method according to an embodiment of the present application;

FIG. 5 is a schematic diagram for acquiring a target measurement point in a wafer measuring method according to an embodiment of the present application; and

FIG. 6 is a schematic diagram of a wafer measuring device according to another embodiment of the present application.

### DETAILED DESCRIPTION

In order to make the objective, technical solutions and advantages of the present application clearer, some embodiments of the present application will be described in detail below with reference to the accompanying drawings. However, it will be apparent to those skilled in the art that, though a number of technical details are presented in some embodiments of the present application in order to provide the reader with a better understanding of the present application, the technical solutions claimed in the present application may be implemented without these technical details and various changes and modifications based on the following some embodiments.

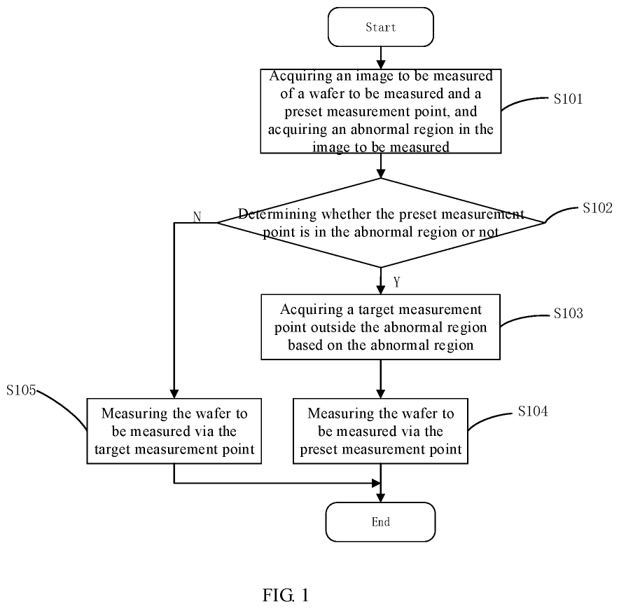

An embodiment of the present application relates to a wafer measuring method, and includes following steps as shown in FIG. 1.

In step S101, an image to be measured of a wafer to be measured and a preset measurement point are acquired, and an abnormal region in the image to be measured is acquired.

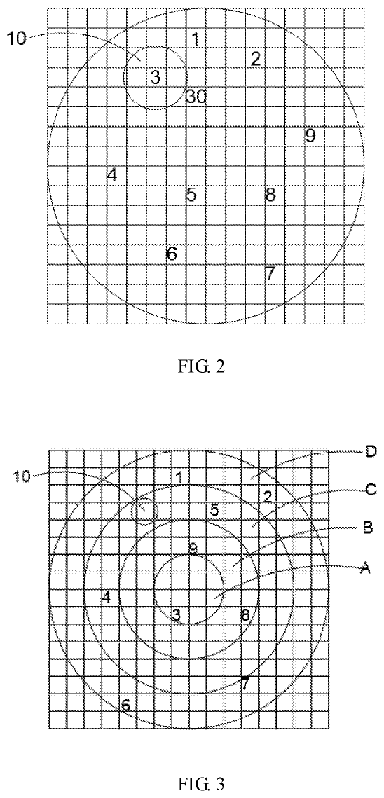

In some examples, the wafer is transferred to a wafer intelligent scanner (WIS) for measurement after being processed by photoetching. As shown in FIG. 2, the WIS may firstly acquire an image of the wafer to be measured as an image to be measured, and also acquire a position of a preset measurement point and a position of an abnormal region 10 in the image to be measured. While measuring the wafer in some embodiments, samples are usually taken on a surface of the wafer to acquire a plurality of preset sample points, such that measurement results acquired by measuring the preset sample points may represent measurement results of the entire wafer. FIG. 2 shows a method for presetting measurement points, which is implemented by dividing the wafer into a plurality of detection units. As shown in FIG. 2, the image to be measured is divided into a plurality of small squares, and each small square is namely a measurement point. Then, all the measurement points are sampled to acquire a plurality of preset measurement points therefrom, such as a measurement point 1, a measurement point 2, a measurement point 3, a measurement point 4, a measurement point 5, a measurement point 6, a measurement point 7, a measurement point 8, and a measurement point 9 in FIG. 2. It shall be understood that dividing the image to be measured into a plurality of small squares is only a specific example of this embodiment and does not constitute a limitation. In other embodiments of the present application, the image to be measured may be divided into a plurality of small hexagons or units of other shapes, which are not listed here and may be configured flexibly according to actual needs.

In some examples, the WIS database stores therein a standard wafer image of a standard wafer, and an area and a position of a region having an abnormality in the image to be measured are acquired by comparing the image to be detected with the standard wafer image. The region having the abnormality may serve as the abnormal region, such as the abnormal region 10 in FIG. 2.

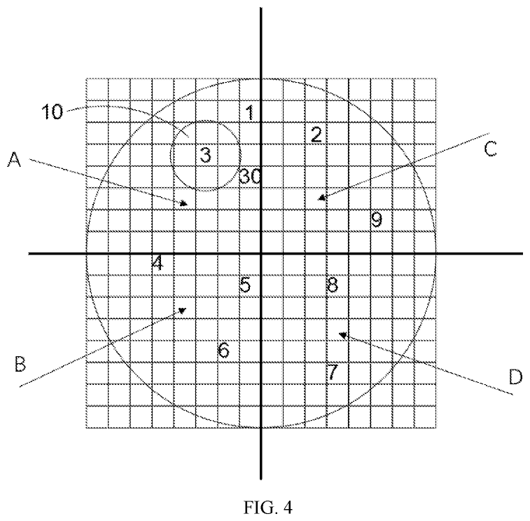

It shall be understood that the foregoing is merely a specific application example for acquiring an abnormal region in some embodiments of the present application, and does not constitute a limitation. In other embodiments of the present application, the abnormal region may be acquired by other methods. As shown in FIG. 3, the image to be measured may for example be divided into four detection regions A, B, C, and D, and the detection region having the abnormality is acquired as the abnormal region. For example, if the abnormality occurs in the detection region C in the case shown in FIG. 3, the detection region C is namely the abnormal region. It shall be understood that dividing the detection region by constructing a plurality of concentric rings as shown in FIG. 3 with the same center as the wafer is merely a specific example of dividing the detection region in some embodiments of the present application, and does not constitute a limitation. In some other embodiments of the present application, except improving the number of detection regions, the dividing may also be implemented by quadrants as shown in FIG. 4 or other methods, which are not listed here and may be configured flexibly according to actual needs.

In step S102, whether the preset measurement point is in the abnormal region or not is determined, and step S103 is performed if yes or step S105 is performed if not.

In some examples, after acquiring positions of the preset measurement point and the abnormal region, whether the preset measurement point is in the abnormal region is determined based on position information of the abnormal region and the preset measurement point. For example, for the measurement point 1, the measurement point 2, the measurement point 3, the measurement point 4, the measurement point 5, the measurement point 6, the measurement point 7, the measurement point 8, and the measurement point 9 in FIG. 2, the measurement point 3 may be marked as an abnormal measurement point if the measurement point 3 is in the abnormal region 10.

It shall be understood that the foregoing is merely a specific application example for determining whether the preset measurement point is in the abnormal region in some embodiments of the present application, and does not constitute a limitation. In other embodiments of the present application, as shown in FIG. 3, the image to be measured may be divided into four detection regions A, B, C, and D, and when one or more of the four detection regions A, B, C, and D are detected to have an abnormality, it is determined whether the preset measurement point is in the detection region having the abnormality. As shown in FIG. 3, if the abnormality 10 is in the detection region C, the measurement points 4 and 5 may be marked as abnormal measurement points. Similarly, the measurement points 1 and 3 in FIG. 4 are also abnormal measurement points.

In step S103, a target measurement point outside the abnormal region is acquired according to the abnormal region.

In some embodiments, if the preset measurement point is in the abnormal region, the preset measurement point in the abnormal region is marked as the abnormal measurement point. Movement is performed by one or more units every time by taking the preset measurement point as a starting point to acquire a detection measurement point, and the target measurement point is acquired once the detection measurement point is outside the abnormal region.

In some examples, as shown in FIG. 5, the abnormal measurement point 3 is taken as the starting point in this embodiment to acquire several units adjacent to the abnormal measurement point as first adjacent units A′. Whether there are one or more first adjacent units A′ outside the abnormal region is determined. If there is one first adjacent unit A′ outside the abnormal region, the first adjacent unit A′ outside the abnormal region serves as the target measurement point; if there is a plurality of first adjacent units A′ outside the abnormal region, one first adjacent unit A′ is sampled randomly from the plurality of first adjacent units A′ outside the abnormal region to serve as the target measurement point; and if there is no first adjacent unit A′ outside the abnormal region, several units adjacent to the first adjacent unit A′ are acquired as second adjacent units B′. Then, whether there are one or more second adjacent units B′ outside the abnormal region is determined. If there is one second adjacent unit B′ outside the abnormal region, the second adjacent unit B′ outside the abnormal region serves as the target measurement point; if there is a plurality of second adjacent units B′ outside the abnormal region, one second adjacent unit B′ is sampled randomly from the plurality of second adjacent units B′ outside the abnormal region to serve as the target measurement point; and if there is no second adjacent unit B′ outside the abnormal region, several units adjacent to the second adjacent unit B′ are acquired as third adjacent units. The subsequent process is performed likewise until the target measurement point is acquired outside the abnormal region. For example, the target measurement point corresponding to the abnormal measurement point 3 in FIG. 2 is marked as 30.

In some examples, whether the target measurement point coincides with other preset measurement points is determined after acquiring the target measurement point. If the target measurement point coincides with other preset measurement points, the aforesaid method is used again to acquire a target measurement point that does not coincide with other preset measurement points. Since the target measurement point and the preset measurement point are configured to have different positions, a reduction in the number of measurement points as caused by a coincidence between the target measurement point and the preset measurement point can be prevented, thereby ensuring accuracy of the measurement result of the wafer to be measured.

It shall be understood that the foregoing is merely a specific application example for acquiring a target measurement point in some embodiments of the present application, and does not constitute a limitation. In other embodiments of the present application, it is also possible to pre-store a plurality of images of abnormal wafers as sample images, and store sample measurement points corresponding to the sample images that include a sample abnormal region of the abnormal wafer. Then, the sample abnormal region having the same distribution with the abnormal region in the image to be measured is acquired as the target sample abnormal region; the sample wafer corresponding to the target sample abnormal region is acquired as the target sample wafer; and the sample measurement point corresponding to the target sample wafer is acquired as the target measurement point. That is, the sample image having the same abnormality distribution and abnormal measurement point distribution with the image to be detected is acquired by comparing the image to be measured with the pre-stored sample images, such that the sample measurement point stored correspondingly with the sample image may be directly acquired as the target measurement point. Thus, what is required is merely the image comparison, and there is no need to perform the complicated calculation, which can effectively simplify the calculation process and improve the efficiency of wafer measurement.

It shall be understood that, in some embodiments of the present application, acquiring the sample abnormal region having the same distribution with the abnormal region may specifically refers to acquiring the sample abnormal region having the same measurement point site with the abnormal region as the target sample abnormal region. Having the same measurement point site indicates that they have the same positions and shapes, such that the target sample abnormal region can be acquired quickly and efficiently, thereby improving the efficiency of wafer measurement. It shall be understood that the foregoing is merely a specific example of some embodiments of the present application, and does not constitute a limitation. In other embodiments of the present application, it is also possible to perform other methods, such as dividing the image to be measured and the sample image into a plurality of detection regions and then acquiring the sample abnormal region that is the same as the detection region where the abnormal region is disposed as the target sample abnormal region, which are not listed here and may be configured flexibly according to actual needs.

In step S104, the wafer to be measured is measured via the target measurement point.

In step S105, the wafer to be measured is measured via the preset measurement point.

Compared with the prior art, in the wafer measuring method according to some embodiments of the present application, the target measurement point disposed outside the abnormal region is acquired by detecting the abnormal region and abnormal measurement point, and the wafer to be measured is measured via the target measurement point, which can effectively avoid the influence of particles, scratches and other defects on the measurement result, thereby effectively improving accuracy of the wafer measurement result.

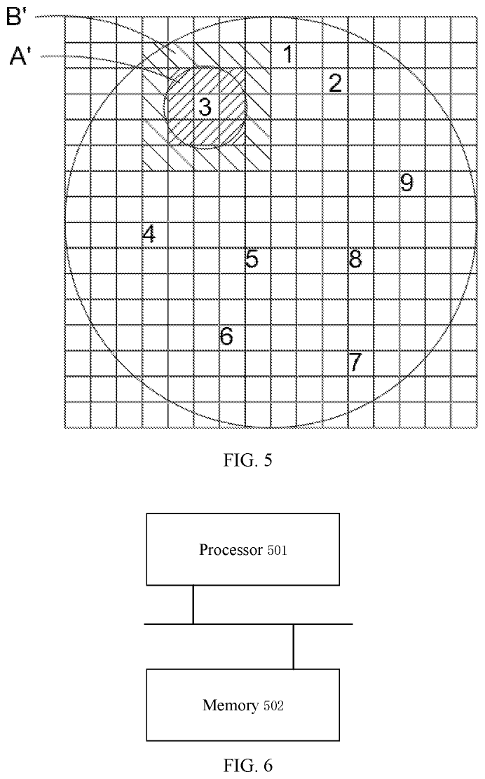

As shown in FIG. 6, another embodiment of the present application relates to a wafer measuring device, which includes at least one processor 501, and a memory 502 communicatively connected with the at least one processor 501. The memory 502 stores instructions executable by the at least one processor 501, such that the instructions, when executed by the at least one processor 501, cause the at least one processor 501 to execute the aforesaid wafer measuring method.

In some examples, the memory 502 and the processor 501 are connected via a bus. The bus may include any number of interconnected buses and bridges, and connect the one or more processors 501 with various circuits of the memory 502. The bus may also connect various other circuits together, such as peripherals devices, voltage regulators, and power management circuits, which are well known in the art and thereby are not further detailed in the present application. A bus interface provides an interface between the bus and a transceiver. The transceiver may be implemented as one element or a plurality of elements, such as a plurality of transmitters and receivers for providing a unit for communicating with various other devices on transmission mediums. Data processed by the processor 501 is transmitted on a wireless medium via an antenna. Furthermore, the antenna receives and then transmits data to the processor 501.

The processor 501 is responsible for managing the bus and general processing, and may further provide various functions, including timing, peripheral interfaces, voltage regulation, power management, and other control functions. The memory 502 may be configured to store data used by the processor 501 during an operation.

Still another embodiment of the present application further provides a computer-readable storage medium for storing computer programs. The computer programs, when executed by a processor, cause the processor to implement the aforesaid method embodiments.

That is, those skilled in the art may understand that all or part of the steps of the method in the aforesaid examples may be completed by instructing relevant hardware via a program. The program is stored in a storage medium and includes several instructions to enable a device (which may be a single-chip microcomputer, a chip, etc.) or a processor to execute all or part of the steps of the method described in respective embodiments of the present application. The aforesaid storage medium may include a medium capable of storing a program code, such as a U disk, a removable hard disk, a read-only memory (ROM), a random access memory (RAM), a magnetic disk, or an optical disk, and the like.

A person of ordinary skill in the art may understand that the above embodiments are specific embodiments for implementing the present application, and in practice, various formal or detail changes may be made without departing from the spirit and scope of the present application.

1. A wafer measuring method, comprising:
acquiring an image to be measured of a wafer to be measured and a preset measurement point, and acquiring an abnormal region in the image to be measured;
acquiring a target measurement point outside the abnormal region based on the abnormal region if the preset measurement point is in the abnormal region; and
measuring the wafer to be measured via the target measurement point.

2. The method according to claim 1, wherein acquiring the abnormal region in the image to be measured comprises:
acquiring an area and a position of a region having an abnormality in the image to be measured by comparing the image to be measured with a standard wafer image; and
taking the region having the abnormality as the abnormal region.

3. The method according to claim 1, wherein there are one or more preset measurement points, and the target measurement point has a different position with the preset measurement point.

4. The method according to claim 1, wherein acquiring the target measurement point outside the abnormal region comprises:
dividing the image to be measured into several units; moving by one or more units every time by taking the preset measurement point as a starting point to acquire a detection measurement point; and acquiring the target measurement point once the detection measurement point is outside the abnormal region.

5. The method according to claim 1, wherein acquiring the target measurement point outside the abnormal region comprises:
pre-storing images of a plurality of abnormal wafers as sample images, the sample images comprising sample abnormal regions and being stored with sample measurement points correspondingly;
acquiring the sample image having the same distribution with the abnormal region as a target sample image; and
acquiring the sample measurement point correspondingly stored with the target sample image as the target measurement point.

6. The method according to claim 5, wherein acquiring the sample image having the same distribution with the abnormal region as the target sample image comprises:
acquiring the sample image having the same area and position with the abnormal region as the target sample image.

7. The method according to claim 5, wherein acquiring the sample image having the same distribution with the abnormal region as the target sample image comprises:
dividing the image to be measured and the sample image into a plurality of detection regions; and
acquiring the sample image that is the same as the detection region where the abnormal region is disposed as the target sample image.

8. The method according to claim 7, wherein the sample measurement point correspondingly stored based on the target sample image serves as the target measurement point.

9. The method according to claim 1, wherein acquiring the abnormal region in the image to be measured comprises:
dividing the image to be measured into a plurality of detection regions; and
acquiring the detection region having an abnormality as the abnormal region.

10. The method according to claim 9, wherein acquiring the target measurement point outside the abnormal region comprises:
acquiring the target measurement point in the detection region adjacent to the abnormal region.

11. The method according to claim 9, wherein dividing the image to be measured into the plurality of detection regions comprises:
dividing the image to be measured into a plurality of annuli or quadrants.

12. A wafer measuring device, comprising:
at least one processor; and
a memory, communicatively connected with the at least one processor; wherein
the memory stores instructions executable by the at least one processor, and the instructions, when executed by the at least one processor, cause the at least one processor to execute the wafer measuring method according to claim 1.
